(19) United States
(12) Patent Application Publication
(10) Pub. No.: US 2013/0223128 A1
(43) Pub. Date: Aug. 29, 2013

(54) VERTICAL RESISTANCE MEMORY DEVICE AND A PROGRAM METHOD THEREOF

(71) Applicant: Samsung Electronics Co., Ltd., (US)

(72) Inventors: Jintaek Park, Hwaseong-si (KR); Jungdal Choi, Hwaseong-si (KR)

(73) Assignee: SAMSUNG ELECTRONICS CO., LTD., Suwon-si (KR)

(21) Appl. No.: 13/708,042

(22) Filed: Dec. 7, 2012

(30) Foreign Application Priority Data
Feb. 27, 2012 (KR) 10-2012-0019762

(51) Int. Cl. G11C 7/00; G11C 11/21

(52) U.S. Cl. CPC G11C 7/00; G11C 11/21
USPC 365/148

(57) ABSTRACT

A method of programming a vertical resistance memory device including a plurality of resistance memory cells arranged in a plurality of blocks includes a step of selecting a block from the plurality of blocks, a step of applying a set voltage to a word line selected from word lines, wherein the selected word line is connected through a corresponding horizontal electrode to a resistance memory cell to be programmed, a step of applying a set-inhibition voltage to unselected word lines of the word lines, a step of applying a bit voltage to a bit line selected from bit lines, wherein the selected bit line is electrically connected to the resistance memory cell via a string selection transistor selected from string selection transistors; and a step of applying a bit-inhibition voltage to unselected bit lines of the bit lines.

### CROSS-REFERENCE TO RELATED APPLICATIONS

A claim for priority under 35 U.S.C. §119 is made to Korean Patent Application No. 10-2012-0019762 filed Feb. 27, 2012, in the Korean Intellectual Property Office, the entire contents of which are incorporated by reference herein in its entirety.

### TECHNICAL FIELD

The inventive concepts described herein relate to a program method of a vertical resistance memory device.

### DISCUSSION OF THE RELATED ART

As a nonvolatile memory device, the flash memory (e.g., a NAND flash memory) provides a high density solution for computer or mobile applications.

Recently, non-volatile memory devices such as a phase random access memory (PRAM), a magnetic RAM (MRAM), and a resistance RAM (ReRAM) have been proposed for a three dimensional storage application. For three-dimensional storage applications of new non-volatile memory devices, especially, ReRAM, an efficient write operation method is demanded.

### SUMMARY

In one embodiment, a method of programming a vertical resistance memory device including a plurality of resistance memory cells arranged in a plurality of blocks includes a step of selecting a block from the plurality of blocks, a step of applying a set voltage to a word line selected from word lines, wherein the selected word line is connected through a corresponding horizontal electrode to a resistance memory cell to be programmed, a step of applying a set-inhibition voltage to unselected word lines of the word lines, a step of applying a bit voltage to a bit line selected from bit lines, wherein the selected bit line is electrically connected to the resistance memory cell via a string selection transistor selected from string selection transistors; and a step of applying a bit-inhibition voltage to unselected bit lines of the bit lines.

Each of the plurality of resistance memory cells includes a variable resistance element having a set state or a reset state determined according to an amount of current flowing through the variable resistance element when the string selection transistor turns on. Each of the plurality of resistance memory cells further includes a diode connected between a corresponding vertical electrode and a corresponding horizontal electrode. The word lines are formed at a plurality of layers, respectively, and vertical electrodes run perpendicular to the plurality of layers. String selection transistors of an unselected block of the plurality of blocks are turned off. Word lines of the unselected block are floated.

In another embodiment, the plurality of resistance memory cells are programmed by a page, the page being formed of resistance memory cells connected to a word line and a part of the bit lines. The set-inhibition voltage is half the set voltage, the bit voltage is 0V, and the bit-inhibition voltage is equal to the set-inhibition voltage.

In still another embodiment, the plurality of resistance memory cells are programmed by a page, the page being formed of resistance memory cells connected to a word line and the bit lines.

In still another embodiment, the programming method also includes a step of applying a string selection voltage to a string selection line connected to a string selection transistor of a string to be selected from the selected block, and a step of applying 0V to a string selection line connected to a string selection transistor of a string to be unselected from the selected block.

In still another embodiment, the resistance memory cell is formed of two variable resistance elements connected between a shared vertical electrode and two divided horizontal electrodes, respectively.

In another embodiment, a method of programming a vertical resistance memory device including a plurality of strings includes a step of applying a set-inhibition voltage to word lines and bit lines of a selected block, a step of applying a set voltage to a word line selected from the word lines, wherein the word line is connected to a resistance memory cell to be programmed, a step of selecting a string having the resistance memory cell to be programmed, and a step of programming the resistance memory cell by applying a bit voltage to a selected bit line from the bit lines.

In still another embodiment, the selecting a string includes providing a string selection voltage to a string selection line connected to a string selection transistor of the selected string.

In still another embodiment, the method of programming also includes a step of verifying the resistance memory cell, after the programming the resistance memory cell.

In one embodiment, a vertical resistance memory device includes a plurality of bit line, a plurality of word lines connected to a plurality of horizontal electrodes, respectively, a plurality of string selection transistors electrically connecting each of the plurality of bit lines and the plurality of vertical electrodes, respectively, a plurality of resistance memory cells connected between the plurality of horizontal electrodes and the plurality of vertical electrodes, respectively, and a control logic configured to control a X-decoder and a page buffer and Y-decoder for programming the plurality of resistance memory cells by a page, wherein the X-decoder selects one of the plurality of word lines and the page buffer and Y-decoder selects one of the bit lines.

The plurality of horizontal electrodes are formed at a plurality of layers disposed over each other, and vertical electrodes run perpendicular to the plurality of layers. Each of the plurality of resistance memory cells includes a variable resistance element having a set state or a reset state determined according to an amount of current flowing through the variable resistance element when a corresponding string selection transistor turns on. The page is formed of resistance memory cells connected to one of the plurality of word lines and a part of the plurality of bit lines.

In another embodiment, the page is formed of resistance memory cells connected to one of the plurality of word lines and the plurality of bit lines.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1 is a schematic diagram for illustrating a vertical resistance memory device according to an embodiment of the inventive concept.

FIG. 2 is a schematic diagram for illustrating the structure of a variable resistance element of a resistance memory cell of FIG. 1.

FIGS. 3A to 3D are schematic circuit diagrams for illustrating the various structures of a resistance memory cell of FIG. 1.

FIG. 4 is a diagram for illustrating a bias condition when a resistance memory cell of FIG. 1 is programmed to a set state by a program operation according to the inventive concept.

FIG. 5 is a timing diagram for illustrating sequence of applying a bias condition when a selected resistance memory cell of FIG. 4 is programmed to a set state under a program operation according to the inventive concept.

FIG. 6 is a diagram illustrating a program bias condition of a vertical resistance memory device according to another embodiment of the inventive concept.

FIG. 7 is a schematic block diagram for illustrating a memory system according to an embodiment of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

Below, a program method of a vertical resistance memory device according to an embodiment of the inventive concept will be described.

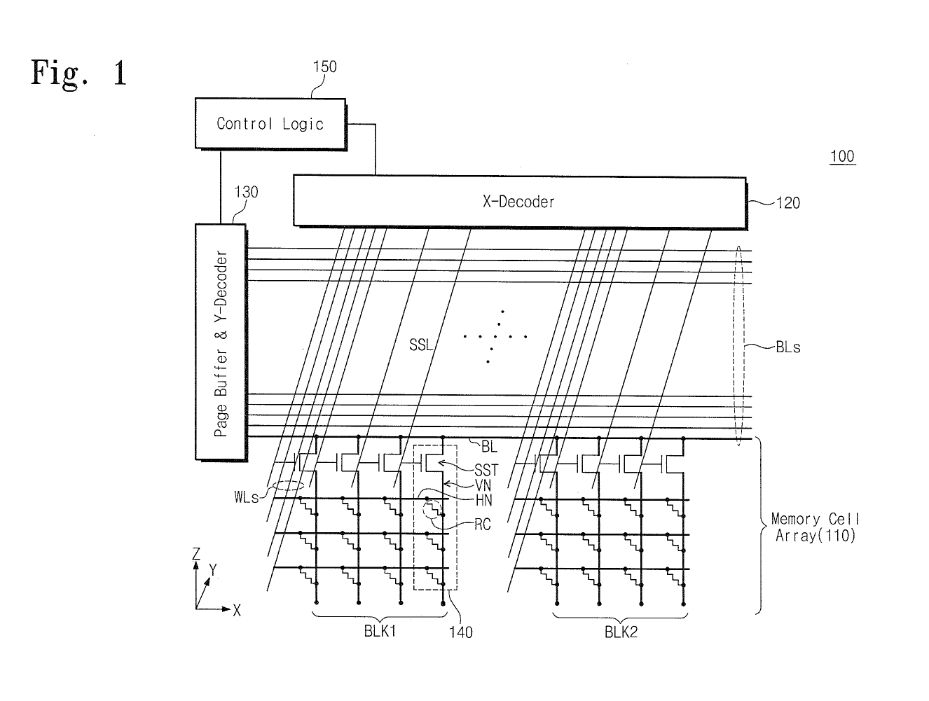

FIG. 1 is a schematic diagram for illustrating a vertical resistance memory device according to an embodiment of the inventive concept. Referring to FIG. 1, a vertical resistance memory device 100 may include a memory cell array 110, a row decoder (hereinafter, referred to as an X-decoder) 120, and a page buffer and column decoder block (hereinafter, referred to as a page buffer and Y-decoder block) 130.

The memory cell array 110 may include a plurality of blocks BLK1 and BLK2. The blocks BLK1 and BLK2 may share bit lines. For ease of description, only two blocks BLK1 and BLK2 are illustrated in FIG. 1. However, the inventive concept is not limited thereto. For example, the memory cell array 110 may be configured to include three or more blocks. Each of the blocks BLK1 and BLK2 may include a plurality of strings that are formed in a direction (e.g., a Z-direction) perpendicular to an XY plane. Directions X, Y, and Z may be perpendicular to one another.

More specifically, a string structure will be described below. A string 140 may include a string selection transistor SST and a plurality of resistance memory cells RC. The one end of the transistor SST may be connected to a bit line BL and the other end of the transistor SST may be connected to the plurality of resistance cells RC. The resistance cells RC may be connected between horizontal electrodes HN and a vertical electrode VN corresponding to the other end of the transistor SST. The horizontal electrodes HN may correspond to word lines WLs, respectively. The horizontal electrodes HN may be formed and placed at different physical layers so that the vertical resistance memory device 100 may be formed in a three-dimensional structure. The vertical electrodes VN may be placed along a first direction (X), respectively. The vertical electrodes VN may be electrically connected to corresponding bit lines BLs via their corresponding string selection transistors SST, respectively. Each of the vertical electrodes VN may run along a third direction (Z) perpendicular to the XY plane.

Each of the resistance memory cells RC may include a variable resistance element. Herein, a variable resistance element may include phase-change materials, transition metal oxides, ferroelectric materials, or magnetic materials. The vertical resistance memory device 100 according to an embodiment of the inventive concept is applicable to a phase-change RAM (PRAM), a resistance RAM (RRAM), a ferroelectric RAM (FRAM), or a magnetic RAM (MRAM) according to a material of a variable resistance element. The variable resistance element may have two memory states such as a set state and a reset state. The memory states may be determined according to the amount of current supplied via a string selection transistor SST.

The string selection transistor SST may be used to determine whether a bit line is connected to a vertical electrode VN. When a string selection voltage Vssl applies to the gate of the transistor SST, the transistor SST turns on and a bit line is electrically connected to a vertical electrode VN. When 0V applies to the gate of the transistor SST, the transistor SST is in an off state and a bit line is electrically disconnected to a vertical electrode VN.

The X-decoder 120 may be connected to word lines and string selection lines of the memory blocks BLK1 and BLK2. The X-decoder 120 may select one of the blocks BLK1 and BLK2 in response to an address. When a block among the blocks BLK1 and BLK2 is selected, word lines WLs and string selection lines SSL of the selected block may be set to a predetermined bias condition for a program operation. When a particular string is selected, a string selection voltage Vssl is provided to a string selection line corresponding to the particular string. The string selection voltage Vssl may be a voltage necessary for turning on a string selection transistor SST.

The page buffer and Y-decoder block 130 may be connected to bit lines. For a program operation, the page buffer and Y-decoder block 130 may receive data to be written to the memory cell array 110 from an external device and store it temporarily. For a read operation, the page buffer and Y-decoder block 130 may read data from the memory cell array 110 and store it temporarily. The page buffer and Y-decoder block 130 may select a specific number of bit lines based on an input address.

The vertical resistance memory device 100 may further include a control logic 140 controlling the X-decoder 120 and the page buffer and Y-decoder block 130 for a program operation and a read operation. The control logic may control the X-decoder 120 and the page buffer and Y-decoder block 130 to perform a program operation by a page.

In exemplary embodiments, a page may be formed of a plurality of resistance memory cells connected to a word line and all bit lines connected to the page buffer 130. In other exemplary embodiments, a page may be formed of a plurality of resistance memory cells connected to a word line and a part of all bit lines connected to the page buffer 130.

The vertical resistance memory device 100 may include a plurality of strings that have resistance memory cells RC connected between horizontal electrodes HN and vertical electrodes VN. The horizontal electrodes HN may be formed a plurality of physical layers so that the vertical resistance memory device 100 may be formed in a three-dimensional structure.

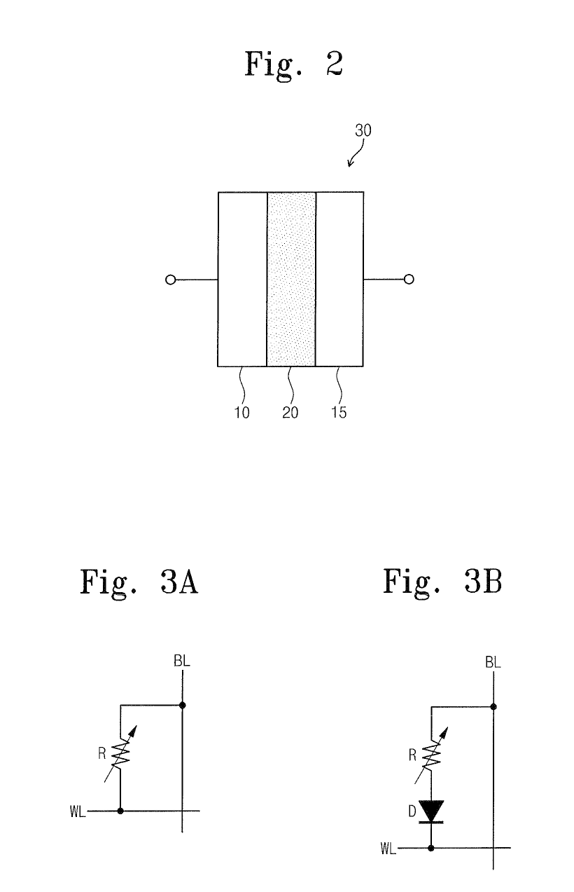

FIG. 2 is a schematic diagram for illustrating the structure of a variable resistance element of a resistance memory cell of FIG. 1. Referring to FIG. 2, the variable resistance element may include a pair of electrodes 10 and 15 and a data storage film 20 interposed between the electrodes 10 and 15.

The electrodes 10 and 15 may be formed of metal, metallic oxide, or metallic nitride. The electrodes 10 and 15 may be formed of Al, Cu, TiN, TixAlyNz, Ir, Pt, Ag, Au, polycrystalline silicon, W, Ti, Ta, TaN, WN, Ni, Co, Cr, Sb, Fe, Mo, Pd, Sn, Zr, Zn, IrO2, StZrO3, or the like.

The data storage film 20 may be formed of a bipolar resistance memory substance or a unipolar resistance memory material. The bipolar resistance memory material may be programmed to a set or reset state according to a polarity of a pulse. The unipolar resistance memory material may be programmed to a set or reset state by a pulse having the same polarity. The unipolar resistance memory material may include transient metal oxide such as NiOx or TiOx, and the bipolar resistance memory material may include materials having the perovskite crystal structure.

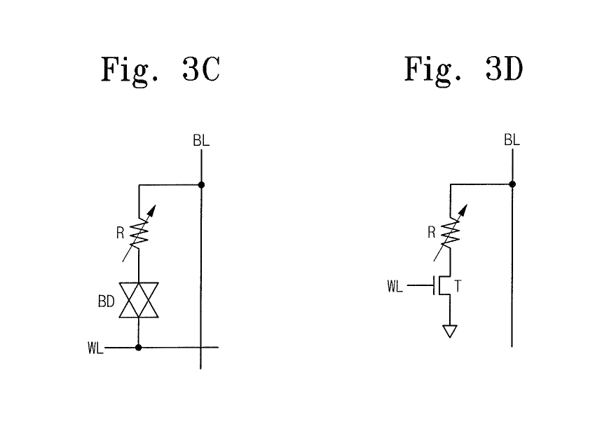

FIGS. 3A to 3D are schematic circuit diagrams for illustrating the various structures of a resistance memory cell of FIG. 1. FIG. 3A illustrates a resistance memory cell not including a selection element. FIGS. 3B to 3D illustrate resistance memory cells including a selection element, respectively.

Referring to FIG. 3A, a resistance memory cell may include a variable resistance element R connected between a bit line BL and a word line WL. A program operation may be performed by applying a voltage across the resistance memory cell connected between the bit line BL and the word line WL.

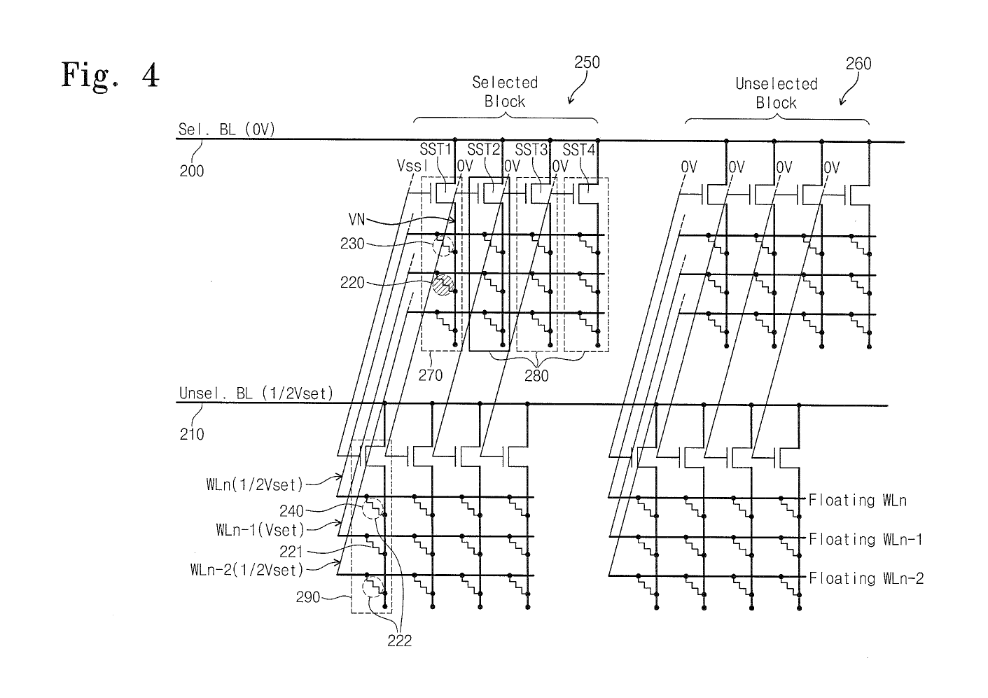

Referring to FIG. 3B, a resistance memory cell may include a variable resistance element R and a diode D. The variable resistance element R may include a variable resistance material for storing data. The diode D may be connected between the variable resistance element R and the word line WL. In another embodiment, the diode D may be connected between the variable resistance element R and the bit line BL. In operation, the diode D may selectively supply a current to the variable resistance element R according to a bias condition of the word line WL and the bit line BL. The diode D may turn on or off according to a voltage difference between the word line WL and the bit line BL. Thus, the resistance memory cell may not be driven when a specific voltage is provided to the word line (or, an unselected word line) WL when the diode D is subject to a reverse bias condition according to a bias condition of the word line and the bit line. The bias condition will be further explained in FIG. 4.

Referring to FIG. 3C, a resistive memory cell may include a variable resistance element R and a bi-directional diode BD. The variable resistance element R may include a variable resistance material for storing data. The bi-directional diode BD may be connected between the variable resistance element R and the word line WL, and the variable resistance element R may be connected between the bit line BL and the bi-directional diode BD. In another embodiment, the variable resistance element R may be connected the word line WL and the bi-directional diode BD. The bi-directional diode BD may block a leakage current flowing to an unselected resistance memory cell.

Referring to FIG. 3D, a resistive memory cell may include a variable resistance element R and a transistor T. The transistor T may be connected between the variable resistance element R and the word line WL. In another embodiment, the transistor may be connected between the variable resistance element R and the bit line BL. In operation, the transistor T may selectively supply a current to the variable resistance element R according to a voltage of the word line WL. The resistive memory cell may be selected when the transistor T is turned on according to a voltage of the word line WL. The resistance memory cell may be unselected when the transistor T is turned off according to a voltage of the word line WL.

A structure of a resistive memory cell is not limited to this disclosure.

FIG. 4 is a diagram for illustrating a bias condition when a resistance memory cell of FIG. 1 is programmed to a set state by a program operation according to the inventive concept. Referring to FIG. 4, for a program operation, a set voltage Vset may be applied to a selected word line WLn-1, and a set-inhibition voltage Vset/2 may be applied to an unselected word line WLn and WLn-2. Also, a bit voltage corresponding to a set state may be applied to a selected bit line 200, and a bit-inhibition voltage may be provided to an unselected bit line 210. In an exemplary embodiment, the bit voltage may be 0V, and the bit-inhibition voltage may be equal to the set-inhibition voltage.

More specifically, with a bias condition of a selected resistance memory cell 220, once a block 250 is selected, a set voltage may be applied to a selected word line WLn-1, and a bit voltage (e.g., 0V) may be applied to a vertical electrode VN. For applying the bit voltage to the vertical electrode VN, the selected bit line 200 is set to the bit voltage. The bit voltage charges the vertical electrode VN via a selected string selection transistor SST1 when a string selection voltage Vssl is applied to a gate of the selected string selection transistor SST1. Under this bias condition where one end of the cell 220 is biased to Vset and the other to the bit voltage (e.g., 0V), the selected cell 220 may have a potential difference corresponding to the set voltage Vset, changing its state to a low resistance state or a set state. In another exemplary embodiment where the selected cell 220 is a multi-level cell, the string selection voltage Vssl may have at least two voltage levels so that the selected string selection transistor SST1 may adjust its driving capability according to the level of the string selection voltage Vssl. The adjusted driving capability may change a resistance value of a resistance cell to have multi-level resistance values according to the level of the string selection voltage Vssl.

With a bias condition of unselected cells 230 in a selected string 270 of the selected block 250, a set-inhibition voltage Vset/2 may be applied to unselected word lines WLn and WLn-2. Under this bias condition, a program operation may be inhibited from programming the unselected cells 230 because a potential difference applied across the unselected cells 230 corresponds to a set-inhibition voltage Vset/2. Herein, the unselected cell 230 subject to the potential difference of a set-inhibition voltage Vset/2 may be referred to as being in set disturbance.

With a bias condition of unselected resistance memory cells in unselected strings 280 in the selected block 250, 0V may be applied to string selection transistors SST2 to SST4 so that the transistors are in an off state and the unselected cells are inhibited from programming while the selected bit line 200 is set to the bit voltage (e.g., 0V).

For inhibiting memory cells of selected string 290 connected to an unselected bit line 210 in the selected block 250 from being programmed to a set state, a bit-inhibition voltage Vset/2 may be applied to an unselected bit line 210. As a result, a resistance cell 221 connected to the selected word line WLn-1 may be subject to the potential difference of a set-inhibition voltage Vset/2, and remaining resistance memory cells 222 connected to the unselected word lines WLn and WLn-2 are subject to the potential difference of 0V. Thus, the resistance memory cells connected to an unselected bit line 210 may be program-inhibited. Herein, the unselected resistance memory cells 222 subject to the potential difference of 0V may be referred to being in reset disturbance.

With a bias condition of an unselected block 260, word lines WLn, WLn-1, and WLn-2 may be floated, 0V may be provided to selected bit lines 200, and a bit-inhibition voltage Vset/2 may be provided to unselected bit lines 210. The string selection transistors may be applied to 0V so that the transistors are in an off state and the unselected cells of the unselected block 260 are inhibited from programming while the selected bit line 200 is set to the bit voltage (e.g., 0V).

A program method of the inventive concept may sequentially program selected resistance memory cells connected to a selected string in a string direction.

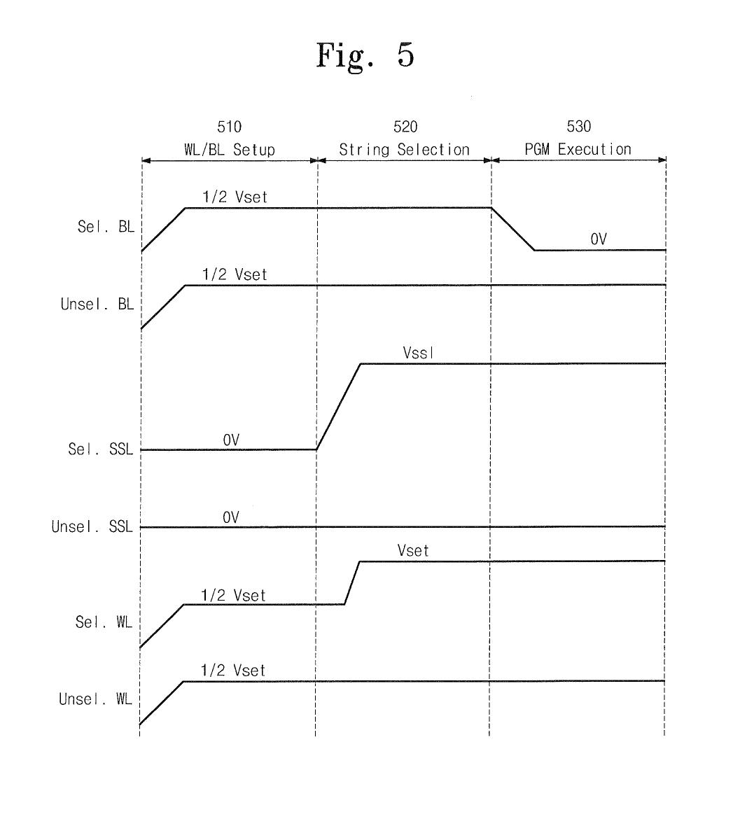

FIG. 5 is a timing diagram for illustrating sequence of applying a bias condition when the selected resistance memory cell 220 of FIG. 4 is programmed to a set state under a program operation according to the inventive concept. Referring to FIG. 5, a program operation may include a bit line/word line setup period 510, a string selection period 520, and a program execution period 530.

For the bit line/word line setup period 510, a bit-inhibition voltage Vset/2 may be applied to bit lines, the selected bit line 200 and the unselected bit line 210 of FIG. 4. A set-inhibition voltage Vset/2 may also be applied to word lines, the selected word lines WLn-1 and the unselected word lines WLn and WLn-2 of FIG. 4. String selection lines of FIG. 4 may be set to 0V.

For the following period of the string selection period 520, a string selection voltage Vssl may be provided to the selected string selection line SSL of FIG. 4 while the other unselected string selection lines maintain 0V as applied for the setup period 510. A set voltage Vset may be applied to the selected word line WLn-1 while the other unselected word lines WLn and WLn-2 maintain the set-inhibition voltage Vset/2 as applied for the setup period 510.

For the following period of the program execution period 530, a bit voltage (e.g., 0V) may be applied to the selected bit line 200 while the unselected bit line 210 may maintain the bit-inhibition voltage Vset/2 as applied for the set up period 510.

As a result of the program operation of FIG. 5 according to the inventive concept, the selected resistance memory cell 220 may be programmed to a set state because the selected resistance memory cell is subject to the potential difference corresponding to a set voltage Vset. The unselected resistance memory cells 230 of the selected string 270 may be program-inhibited because the unselected cells 230 may be subject to the potential difference corresponding to a set-inhibition voltage Vset/2.

While the program operation is performed on the selected string, the unselected string selection lines connected to the selected bit line 200 may maintains 0V as set for the setup period of 510. As a result, resistance memory cells in an unselected string 280 may be program-inhibited because no current flows through the resistance memory cells.

For the program operation, the unselected bit line 210 may maintain 0V as set for the setup period of 510 so that the resistance memory cells of the unselected strings 290 may be program-inhibited.

Although not shown in FIG. 5, following the program execution period, a verification-read operation may be executed to confirm whether programming is normally performed.

A vertical resistance memory device of the inventive concept may have various structures for a high integration purpose.

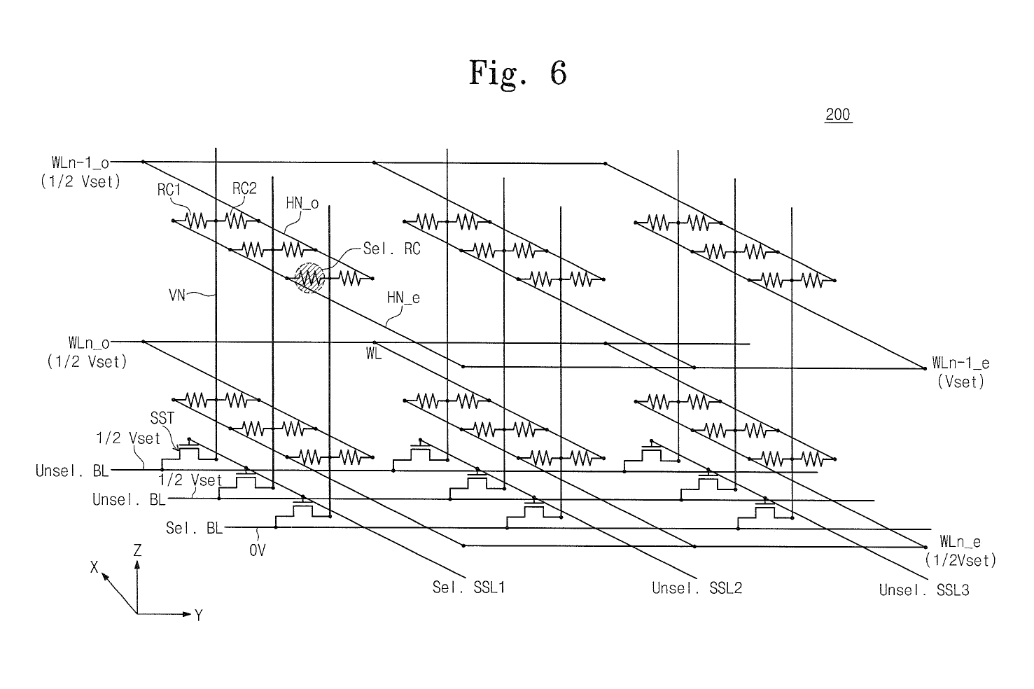

FIG. 6 is a diagram illustrating a program bias condition of a vertical resistance memory device according to another embodiment of the inventive concept. Referring to FIG. 6, a vertical resistance memory device 200 may have a different horizontal structure from that of FIG. 1. The vertical resistance memory device 200 may have the resistance memory cell formed of two variable resistance elements RC1 and RC2 that is connected between a shared vertical electrode VN and two divided horizontal electrodes HN_o and HN_e, respectively. For example, the horizontal structure may have two horizontal electrodes, an odd horizontal electrode HN_o and an even horizontal electrode HN_e, at the same layer. Herein, the odd horizontal electrode HN_o may correspond to one odd word line (e.g., WLn-1_o), and the even horizontal electrode HN_e may correspond to one even word line (e.g., WLn-1_e). The two electrodes HN_o and HN_e may share a vertical electrode VN. A string structure of FIG. 6 may be substantially identical to that of FIG. 1 except the difference explained above.

In FIG. 6, a program bias condition may be substantially identical to that described in FIGS. 1 to 8. For example, a set voltage Vset may be applied to a selected word line WLn-1_e, and a set-inhibition voltage Vset/2 may be applied to unselected word lines WLn_e, WLn_o, and WLn-1_o. Also, a bit voltage of 0V may be applied to selected bit lines, a bit-inhibition voltage Vset/2 to an unselected bit line, a string selection voltage Vssl to a selected string selection line SSL1, and 0V to unselected string selection lines SSL2 and SSL3.

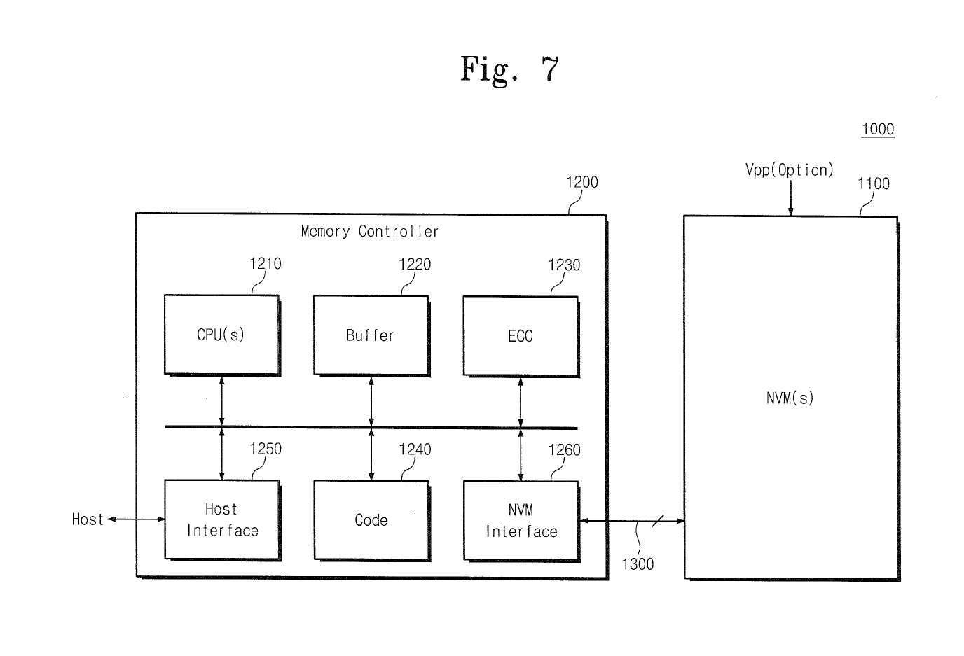

FIG. 7 is a schematic block diagram for illustrating a memory system according to an embodiment of the inventive concept. Referring to FIG. 10, a memory system 1000 may include at least one nonvolatile memory device 1100 and a memory controller 1200.

The nonvolatile memory device 1100 may be optionally supplied with a high voltage Vpp from the outside. The nonvolatile memory device 1100 may be substantially identical to the vertical resistance memory device 100 of FIG. 1.

The memory controller 1200 may be connected with the nonvolatile memory device 1100 via a plurality of channels 1300. The memory controller 1200 may include at least one Central Processing Unit (CPU) 1210, a buffer memory 1220, an ECC circuit 1230, a code 1240, a host interface 1250, and a memory interface 1260. Although not shown in FIG. 10, the memory controller 1200 may further comprise a randomization circuit that randomizes and de-randomizes data. The memory system 1000 according to an embodiment of the inventive concept is applicable to a perfect page new (PPN) memory.

Detailed description of the memory system is disclosed in U.S. Pat. No. 8,027,194 and U.S. Patent Publication No. 2010/0082890, the entirety of which is hereby incorporated by reference.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A method of programming a vertical resistance memory device including a plurality of resistance memory cells arranged in a plurality of blocks comprising:
selecting a block from the plurality of blocks;
applying a set voltage to a word line selected from word lines, wherein the selected word line is connected through a corresponding horizontal electrode to a resistance memory cell to be programmed;
applying a set-inhibition voltage to unselected word lines of the word lines;
applying a bit voltage to a bit line selected from bit lines, wherein the selected bit line is electrically connected to the resistance memory cell via a string selection transistor selected from string selection transistors; and
applying a bit-inhibition voltage to unselected bit lines of the bit lines.

2. The method of claim 1, wherein each of the plurality of resistance memory cells includes a variable resistance element having a set state or a reset state determined according to an amount of current flowing through the variable resistance element when the string selection transistor turns on.

3. The method of claim 2, wherein each of the plurality of resistance memory cells further includes a diode connected between a corresponding vertical electrode and a corresponding horizontal electrode.

4. The method of claim 1, wherein the word lines are formed at a plurality of layers disposed over each other, and vertical electrodes runs perpendicular to the plurality of layers.

5. The method of claim 1, wherein the plurality of resistance memory cells are programmed by a page, the page being formed of resistance memory cells connected to a word line and a part of the bit lines.

6. The method of claim 1, wherein the plurality of resistance memory cells are programmed by a page, the page being formed of resistance memory cells connected to a word line and the bit lines.

7. The method of claim 1, wherein string selection transistors of an unselected block of the plurality of blocks are turned off.

8. The method of claim 7, wherein word lines of the unselected block are floated.

9. The method of claim 1, further comprising:
applying a string selection voltage to a string selection line connected to a string selection transistor of a string to be selected from the selected block.

10. The method of claim 9, further comprising:
applying 0V to a string selection line connected to a string selection transistor of a string to be unselected from the selected block.

11. The method of claim 1, wherein the set-inhibition voltage is half the set voltage, the bit voltage is 0V, and the bit-inhibition voltage is equal to the set-inhibition voltage.

12. The method of claim 1, wherein the resistance memory cell is formed of two variable resistance elements connected between a shared vertical electrode and two divided horizontal electrodes, respectively.

13. A method of programming a vertical resistance memory device including a plurality of strings, the method comprising:
applying a set-inhibition voltage to word lines and bit lines of a selected block;
applying a set voltage to a word line selected from the word lines, wherein the word line is connected to a resistance memory cell to be programmed;
selecting a string having the resistance memory cell to be programmed; and
programming the resistance memory cell by applying a bit voltage to a selected bit line from the bit lines.

14. The method of claim 13, wherein the selecting a string comprises providing a string selection voltage to a string selection line connected to a string selection transistor of the selected string.

15. The method of claim 13, further comprising:
verifying the resistance memory cell, after the programming the resistance memory cell.

16. A vertical resistance memory device comprising:
a plurality of bit line;
a plurality of word lines connected to a plurality of horizontal electrodes, respectively;
a plurality of string selection transistors electrically connecting each of the plurality of bit lines and the plurality of vertical electrodes, respectively;
a plurality of resistance memory cells connected between the plurality of horizontal electrodes and the plurality of vertical electrodes, respectively; and
a control logic configured to control a X-decoder and a page buffer and Y-decoder for programming the plurality of resistance memory cells by a page, wherein the X-decoder selects one of the plurality of word lines and the page buffer and Y-decoder selects one of the bit lines.

17. The device of claim 16, wherein the plurality of horizontal electrodes are formed at a plurality of layers disposed over each other, and vertical electrodes run perpendicular to the plurality of layers.

18. The device of claim 17, wherein each of the plurality of resistance memory cells includes a variable resistance element having a set state or a reset state determined according to an amount of current flowing through the variable resistance element when a corresponding string selection transistor turns on.

19. The device of claim 17, wherein the page is formed of resistance memory cells connected to one of the plurality of word lines and a part of the plurality of bit lines.

20. The device of claim 17, wherein the page is formed of resistance memory cells connected to one of the plurality of word lines and the plurality of bit lines.
